(19) United States
(12) Patent Application Publication
(10) Pub. No.: US 2026/0246229 A1
(43) Pub. Date: Aug. 20, 2026

(54) Semiconductor Optical Integrated Device

(71) Applicant: NTT, Inc., Tokyo (JP)

(72) Inventors: Wataru Kobayashi, Musashino-shi, Tokyo (JP); Meishin Chin, Musashino-shi, Tokyo (JP)

(21) Appl. No.: 19/160,667

(22) PCT Filed: Apr. 24, 2023
(86) PCT No.: PCT/JP2023/016129

§ 371 Date: Aug. 28, 2025

(51) Int. Cl. H01S 5/026; H01S 5/12

(52) U.S. Cl. CPC H01S 5/0264; H01S 5/0265; H01S 5/12

(57) ABSTRACT

A semiconductor optical integrated device includes a semiconductor laser, an optical modulator that modulates light emitted from the semiconductor laser to generate signal light, an optical waveguide that propagates the signal light, a gain waveguide formed adjacent to the optical waveguide, and a light receiving unit connected to the gain waveguide, which are monolithically integrated. A gain of the gain waveguide is varied by part of the signal light from the optical waveguide, and the light receiving unit acquires an intensity of natural radiation amplified light propagating through the gain waveguide.

### TECHNICAL FIELD

The present disclosure relates to a semiconductor optical integrated device.

### BACKGROUND ART

Patent Literature 1 discloses a semiconductor laser light source in which light emitted from a semiconductor laser is divided into monitor light and signal light incident on a light receiving unit by a branching unit, and a current amount of the semiconductor laser is controlled based on a light intensity of the monitor light, thereby maintaining a light intensity of the signal light constant.

Patent Literature 2 discloses a semiconductor optical integrated device in which an optical integrated element including a semiconductor laser and an optical amplifier receives reflected light of part of light emitted from the optical integrated element and controls a current amount of the semiconductor laser based on a light intensity of the reflected light, thereby maintaining a light intensity of the light emitted from the optical integrated element constant.

Patent Literature 3 discloses a semiconductor optical integrated device having a configuration in which light emitted from an optical integrated element including an optical amplifier is received by an external light receiving unit, and a light intensity of the emitted light is measured.

### CITATION LIST

### Patent Literature

[Patent Literature 1] JP 6849524 B2
[Patent Literature 2] JP 6761390 B2
[Patent Literature 3] JP 6761391 B2

### SUMMARY OF THE INVENTION

### Technical Problem

According to the techniques described in Patent Literatures 1 to 3, it is necessary to separately provide a configuration for measuring the light intensity of the light emitted from the semiconductor laser or the optical integrated element, and there is a problem that the entire module including the semiconductor laser or the optical integrated element increases in size.

The present disclosure has been made in view of the above problem. An object of the disclosure is to provide a semiconductor optical integrated device that can measure a light intensity of emitted light while suppressing an increase in size of the entire module.

### Solution to Problem

In order to solve the above-described problem, a semiconductor optical integrated device according to an aspect of the present disclosure includes a semiconductor laser, an optical modulator that modulates light emitted from the semiconductor laser to generate signal light, an optical waveguide that propagates the signal light, a gain waveguide formed adjacent to the optical waveguide, and a light receiving unit connected to the gain waveguide, which are monolithically integrated. A gain of the gain waveguide is varied by part of the signal light from the optical waveguide, and the light receiving unit acquires an intensity of natural radiation amplified light propagating through the gain waveguide.

### Advantageous Effects of the Invention

According to the present disclosure, it is possible to measure a light intensity of emitted light while suppressing an increase in size of the entire module.

### BRIEF DESCRIPTION OF DRAWINGS

FIG. 1 is a schematic view illustrating a configuration of a semiconductor optical integrated device according to a first embodiment of the present disclosure.

FIG. 2 is a cross-sectional view taken along line A-A in FIG. 1.

FIG. 3 is a cross-sectional view taken along line B-B in FIG. 1.

FIG. 4 is a cross-sectional view taken along line C-C in FIG. 1.

FIG. 5 is a diagram showing an example of a relationship between an input light intensity to a gain waveguide and a gain in a case where a waveguide length is changed.

FIG. 6 is a diagram showing an example of a relationship between an input light intensity to a gain waveguide and a gain in a case where an injection current is changed.

FIG. 7 is a view illustrating a manufacturing process (first half) of the semiconductor optical integrated device according to the first embodiment of the present disclosure.

FIG. 8 is a view illustrating a manufacturing process (second half) of the semiconductor optical integrated device according to the first embodiment of the present disclosure.

FIG. 9 is a detailed cross-sectional view taken along line A-A in FIG. 1.

FIG. 10 is a schematic view illustrating a configuration of a semiconductor optical integrated device according to a second embodiment of the present disclosure.

FIG. 11 is a view illustrating a manufacturing process of the semiconductor optical integrated device according to the second embodiment of the present disclosure.

FIG. 12 is a schematic view illustrating a configuration of a semiconductor optical integrated device according to a third embodiment of the present disclosure.

FIG. 13 is a schematic view illustrating a configuration of a semiconductor optical integrated device according to a fourth embodiment of the present disclosure.

### DESCRIPTION OF EMBODIMENTS

Next, embodiments of the present disclosure will be described in detail with reference to the drawings. In the description, the same components are denoted by the same reference signs, and redundant description will be omitted.

### Description of First Embodiment

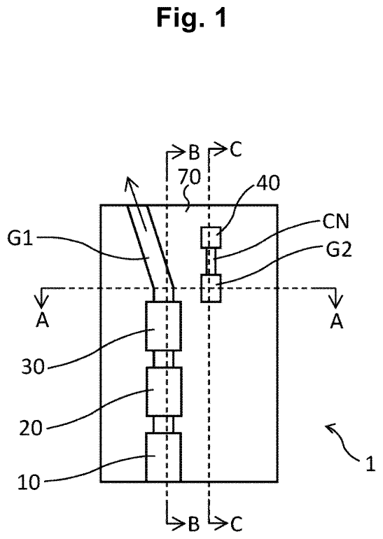

FIG. 1 is a schematic view illustrating a configuration of a semiconductor optical integrated device according to a first embodiment of the present disclosure. A semiconductor optical integrated device 1 includes a semiconductor laser 10, an optical modulator 20, an optical waveguide G1, a gain waveguide G2, and a light receiving unit 40. In addition, the semiconductor optical integrated device 1 may include an optical amplifier 30. The semiconductor laser 10, the optical modulator 20, the optical amplifier 30, the optical waveguide G1, the gain waveguide G2, and the light receiving unit 40 are monolithically integrated on the same substrate.

The semiconductor laser 10 is, for example, a distributed feedback (DFB) laser that generates light of a carrier wave. The DFB laser is excellent in a single wavelength property.

The optical modulator 20 modulates light emitted from the semiconductor laser 10 to generate signal light. The optical modulator 20 is, for example, an electroabsorption (EA) modulator for modulating the carrier wave generated by the semiconductor laser 10.

An integrated element (EA-DFB laser) configured by monolithically integrating the semiconductor laser 10 (DFB laser) and the optical modulator 20 (EA modulator) on a single substrate is used as a light emitting device for long-distance transmission with a transmission distance of 40 km or more. As a wavelength of the signal light, a 1.55 μm band in which propagation loss of an optical fiber is small or a 1.3 μm band in which the signal light is hardly affected by wavelength dispersion generated in the optical fiber is mainly used. The wavelength of the signal light emitted from the EA-DFB laser is not limited to the example described herein.

In order to maintain the intensity of the signal light output from the integrated element constant, control is performed in which the intensity of the signal light is indirectly measured by the light receiving unit 40 to be described later, and an amount of current to be supplied to the semiconductor laser 10 is adjusted based on the measured intensity. Even when the semiconductor optical integrated device 1 is operated for a long period of time, the intensity of the signal light is adjusted so as to be maintained constant.

The optical amplifier 30 amplifies the signal light output from the optical modulator 20. For example, the optical amplifier 30 generates induced radiation based on incident signal light to amplify the signal light.

The optical waveguide G1 propagates the signal light output from the optical amplifier 30. When the semiconductor optical integrated device 1 does not include the optical amplifier 30, the optical waveguide G1 may propagate signal light output from the optical modulator 20.

The gain waveguide G2 is formed adjacent to the optical waveguide G1, and is configured such that a gain varies by part of the signal light from the optical waveguide G1. More specifically, a distance between the optical waveguide G1 and the gain waveguide G2 is set such that signal light leaking from the optical waveguide G1 reaches the gain waveguide G2, and a gain of the gain waveguide G2 varies due to the leaking signal light.

For example, as illustrated in FIG. 1, a semiconductor region 70 exists between the optical waveguide G1 and the gain waveguide G2. Part of the signal light leaks from the optical waveguide G1 and enters the semiconductor region 70 while propagating through the optical waveguide G1. Then, part of the signal light reaches the gain waveguide G2 from the optical waveguide G1 via the semiconductor region 70.

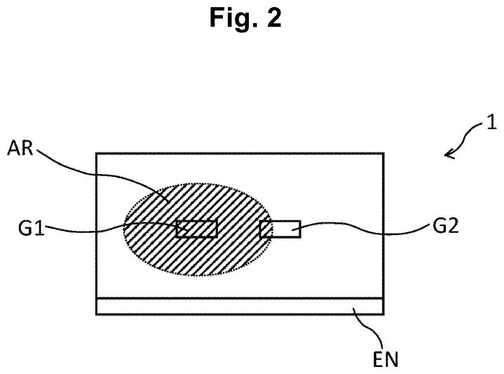

FIG. 2 is a cross-sectional view taken along line A-A in FIG. 1. In FIG. 2, a range in which an intensity of the signal light leaking from the optical waveguide G1 is a predetermined threshold or more is illustrated as a region AR. The gain waveguide G2 is arranged at a position overlapping the region AR. The region AR is determined based on a cross-sectional shape of the optical waveguide G1. Therefore, the distance between the optical waveguide G1 and the gain waveguide G2 may be set based on at least one of the thickness and the width of the optical waveguide G1.

A predetermined current (injection current) is injected into the gain waveguide G2, and when part of the signal light reaches the gain waveguide G2, natural radiation amplified light is generated by induced radiation in the gain waveguide G2.

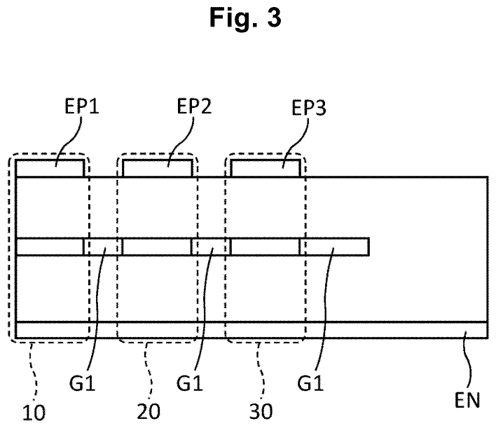

FIG. 3 is a cross-sectional view taken along line B-B in FIG. 1. As illustrated in FIG. 3, the optical waveguide G1 introduces light output from the semiconductor laser 10 into the optical modulator 20, then introduces signal light after being modulated by the optical modulator 20 into the optical amplifier 30, and then guides the signal light toward an end surface of the semiconductor optical integrated device 1.

In FIG. 3, electrodes EP1, EP2, EP3, and EN for controlling operations of the semiconductor laser 10, the optical modulator 20, and the optical amplifier 30 are illustrated.

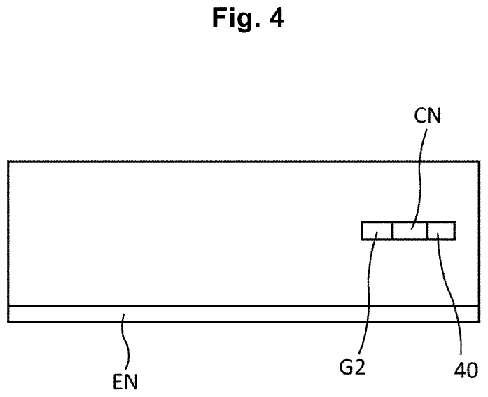

FIG. 4 is a cross-sectional view taken along line C-C in FIG. 1. As illustrated in FIG. 4, the gain waveguide G2 is connected to the light receiving unit 40. For example, the gain waveguide G2 and the light receiving unit 40 are connected to each other by a connection path CN.

The connection path CN is configured to propagate the natural radiation amplified light and not to propagate the signal light. More specifically, the connection path CN is thinner than a single mode, and has a structure in which a waveguide mode of normal signal light cannot propagate through thereof. For example, when the width of the connection path CN is narrower than 3 μm, it is difficult to perform single mode waveguide with respect to generally used signal light. In addition, when the width of the connection path CN is 1 μm, it is difficult to confine an electric field intensity.

In order to suppress optical coupling of the signal light propagating through the optical waveguide G1 to the gain waveguide G2, and configure the gain waveguide G2 and the connection path CN so as to propagate only the natural radiation amplified light, the widths of the gain waveguide G2 and the connection path CN may be narrower than 3 μm.

The light receiving unit 40 is connected to the gain waveguide G2 and acquires an intensity of light propagating through the gain waveguide G2.

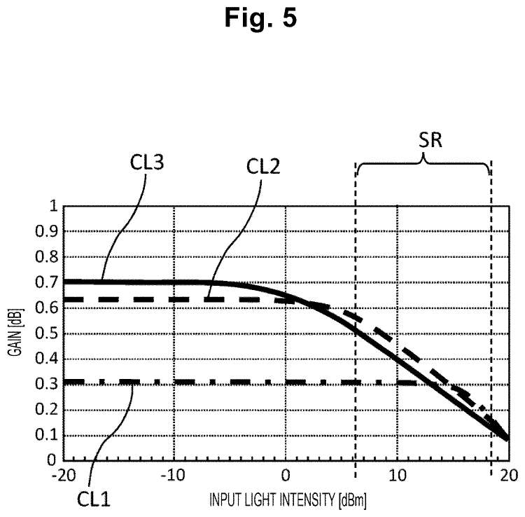

FIG. 5 is a diagram showing an example of a relationship between an input light intensity to a gain waveguide and a gain in a case where a waveguide length is changed. In FIG. 5, graphs CL1, CL2, and CL3 show relationships between the input light intensity to the gain waveguide G2 and the gain of the gain waveguide G2 in a case where the waveguide length of the gain waveguide G2 is 10 μm, 20 μm, and 30 μm, respectively. The injection current is 5 mA.

As shown in FIG. 5, it can be seen that the longer the waveguide length of the gain waveguide G2, the wider the range of the input light intensity (gain saturation range SR of the gain waveguide G2) in which the gain changes according to the change in the input light intensity.

In the present disclosure, the intensity of the signal light leaking from the optical waveguide G1 is acquired by the light receiving unit 40 via the natural radiation amplified light generated in the gain waveguide G2. Therefore, when the semiconductor optical integrated device 1 is used, the gain of the gain waveguide G2 is varied in the gain saturation range SR of the gain waveguide G2.

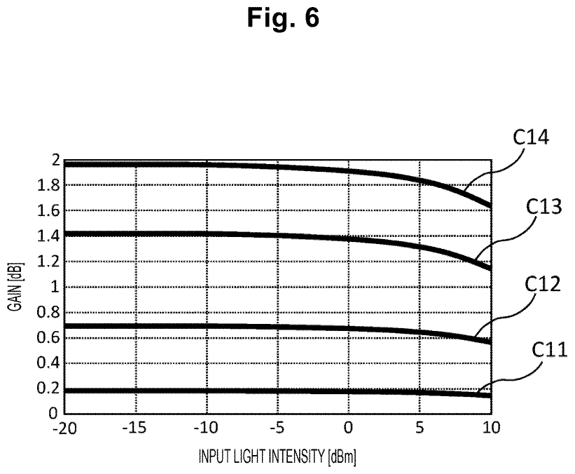

FIG. 6 is a diagram showing an example of a relationship between an input light intensity to a gain waveguide and a gain in a case where the injection current to the gain waveguide G2 is changed. In FIG. 6, graphs CL11, CL12, CL13, and CL14 show relationships between the input light intensity to the gain waveguide G2 and the gain of the gain waveguide G2 in a case where the injection current is 2.5 mA, 5 mA, 10 mA, and 15 mA, respectively.

When a current is injected into the gain waveguide G2, the natural radiation amplified light is generated. The gain waveguide G2 gives a gain according to a light intensity of incident light. According to FIG. 6, when the input light intensity changes from 0 dBm to 5 dBm, a gain difference of about 0.1 dB is given at the waveguide length of the gain waveguide G2 of 30 μm and the injection current of 15 mA. A value correlated with the input light intensity can be observed by monitoring this gain difference as a current value.

The intensity of the signal light leaking from the optical waveguide G1 also changes according to the intensity of the signal light propagating through the optical waveguide G1. As a result, the intensity of the natural radiation amplified light changes, and the gain of the gain waveguide G2 varies. Therefore, the intensity of the signal light can be monitored by monitoring the gain difference of the gain waveguide G2.

In other words, it can be said that the light receiving unit 40 indirectly measures the intensity of the signal light propagating through the optical waveguide G1 by monitoring the gain of the gain waveguide G2. The intensity of the signal light can be adjusted so as to be maintained constant by performing control to adjust the amount of current to be supplied to the semiconductor laser 10 based on the gain of the gain waveguide G2. As a result, even when the semiconductor optical integrated device 1 is operated for a long period of time, the intensity of the signal light can be kept constant.

### Manufacturing Process of Semiconductor Optical Integrated Device

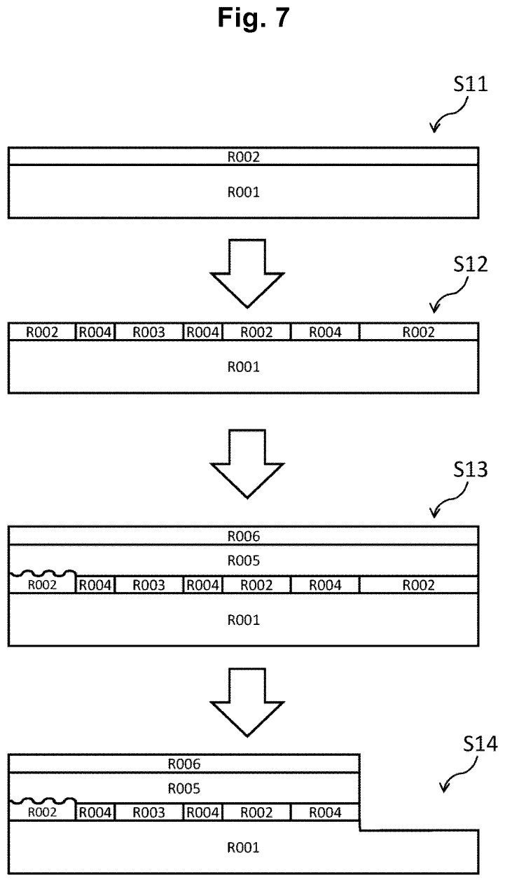

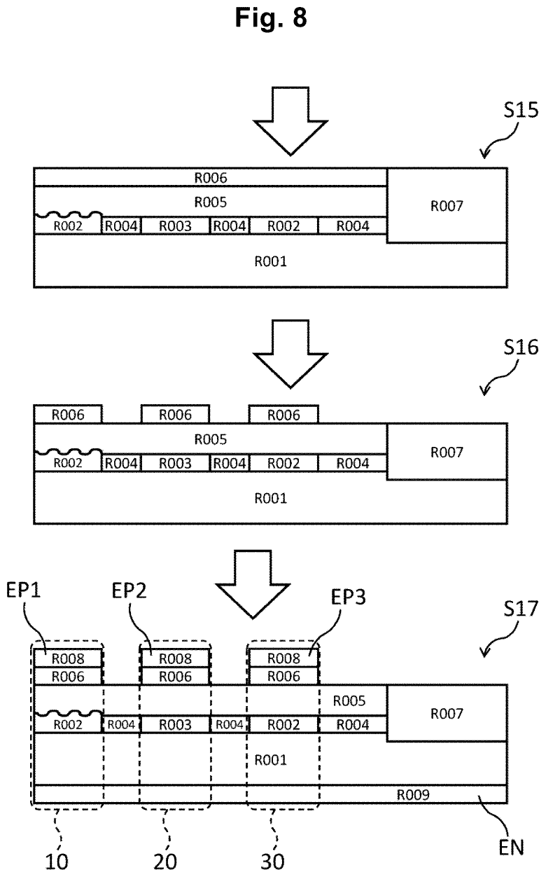

Next, a manufacturing process of the semiconductor optical integrated device 1 will be described with reference to FIGS. 7 and 8. FIG. 7 is a view illustrating a manufacturing process (first half) of the semiconductor optical integrated device according to the first embodiment of the present disclosure. FIG. 8 is a view illustrating a manufacturing process (latter half) of the semiconductor optical integrated device according to the first embodiment of the present disclosure.

FIG. 7 illustrates states S11 to S14 in the manufacturing process of the semiconductor optical integrated device 1. FIG. 8 illustrates states S15 to S17 in the manufacturing process of the semiconductor optical integrated device 1.

First, a layer R002 that is a layer that functions as the semiconductor laser 10, the optical amplifier 30, and the gain waveguide G2 is formed on a layer R001 of an n-polar indium phosphide (InP) substrate to obtain state S11.

Subsequently, a layer R003 that functions as the optical modulator 20 and the light receiving unit 40, and a layer R004 that functions as the optical waveguide G1 and the connection path CN are formed using a butt joint process to obtain state S12. Note that, when the butt joint process is performed, the gain waveguide G2, the connection path CN, and the light receiving unit 40 are simultaneously formed.

Thereafter, a diffraction grating is formed on an upper surface of the layer R002 that functions as the semiconductor laser 10, and further, a layer R005 of a p-polar indium phosphide (InP) and a layer R006 of a p+-polar indium gallium arsenide (InGaAs) are overcladding grown to obtain state S13.

Subsequently, the semiconductor layer is processed by dry etching or the like to obtain state S14.

Thereafter, each component and a side of the waveguide are buried in a layer R007 of a semi-insulating InP doped with iron (Fe) to obtain state S15.

Subsequently, the components are electrically separated from each other by removing the layer R006 between the semiconductor laser 10, the optical modulator 20, and the optical amplifier 30 to obtain state S16.

Thereafter, a layer R008 to be an electrode for p-polarity is formed on the layer R006 of each component, and a layer R009 to be a back electrode is formed. The layer R008 functions as the electrodes EP1, EP2, and EP3. The layer R009 functions as the electrode EN. As a result, state S17 is obtained.

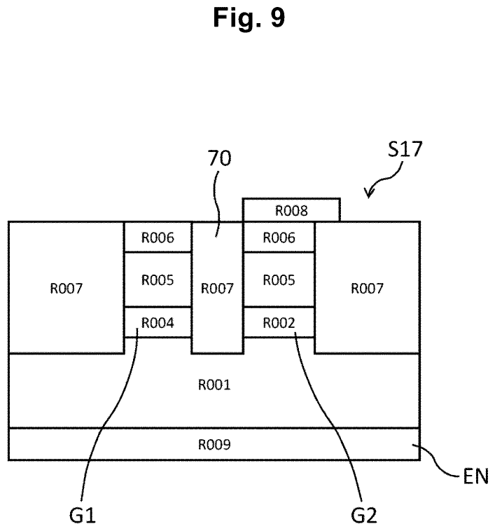

FIG. 9 is a detailed cross-sectional view taken along line A-A in FIG. 1. As illustrated in FIG. 9, a space between the optical waveguide G1 and the gain waveguide G2 is buried in the layer R007. The layer R007 between the optical waveguide G1 and the gain waveguide G2 functions as the semiconductor region 70, and has a function of propagating part of the signal light leaking from the optical waveguide G1 to the gain waveguide G2. A region of the optical waveguide G1 and the gain waveguide G2 except for a region where part of signal light propagates through thereof may have various structures such as a high-mesa structure and a ridge structure.

In the present disclosure, the distance between the optical waveguide G1 and the gain waveguide G2 is set to 5 μm, and the region AR indicating the signal light leaking from the optical waveguide G1 is designed to overlap the gain waveguide G2. The arrangement of the optical waveguide G1 and the gain waveguide G2 is not limited to the example described herein.

### Description of Second Embodiment

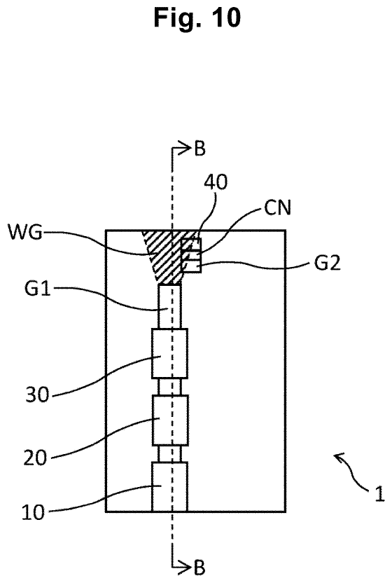

FIG. 10 is a schematic view illustrating a configuration of a semiconductor optical integrated device according to a second embodiment of the present disclosure. Unlike the first embodiment illustrated in FIG. 1, the semiconductor optical integrated device 1 illustrated in FIG. 10 includes a window structure region WG. The window structure region WG propagates the signal light from the optical waveguide G1 to the end surface of the semiconductor optical integrated device 1.

The signal light emitted from an end portion of the optical waveguide G1 travels so that a width in a direction perpendicular to a traveling direction increases while propagating through the window structure region WG. For example, when a diameter of an electric field intensity while propagating through the optical waveguide G1 is 2 μm, the diameter of the electric field intensity increases to 7.2 μm when the signal light travels through the window structure region WG by 20 μm.

Therefore, it is possible to design such that part of the signal light overlaps the gain waveguide G2 by arranging the gain waveguide G2 in accordance with the increase of the signal light traveling through the window structure region WG.

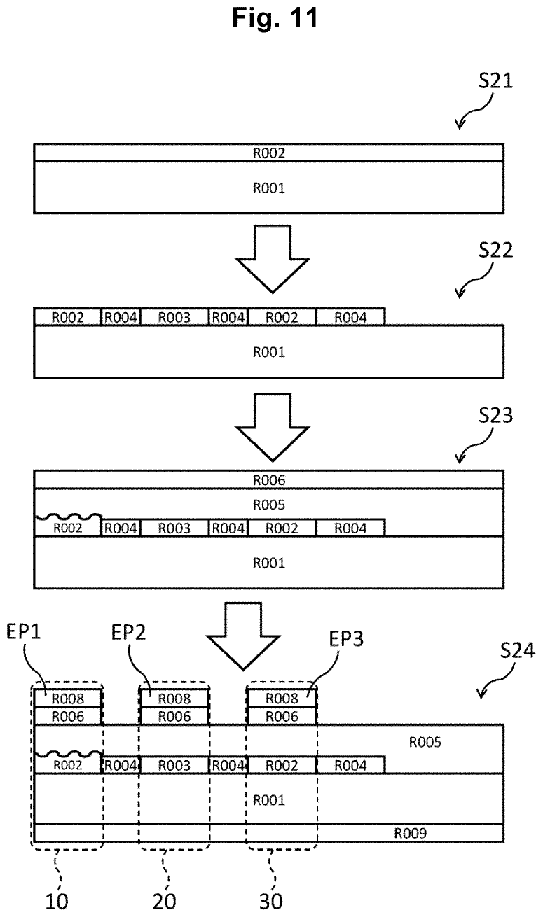

FIG. 11 is a view illustrating a manufacturing process of the semiconductor optical integrated device according to the second embodiment of the present disclosure. FIG. 11 illustrates states S21 to S24 in the manufacturing process of the semiconductor optical integrated device 1.

First, a layer R002 that is a layer that functions as the semiconductor laser 10, the optical amplifier 30, and the gain waveguide G2 is formed on a layer R001 of an n-polar indium phosphide (InP) substrate to obtain state S21.

Subsequently, a layer R003 that functions as the optical modulator 20 and the light receiving unit 40, and a layer R004 that functions as the optical waveguide G1 and the connection path CN are formed using a butt joint process to obtain state S12. Note that, when the butt joint process is performed, the gain waveguide G2, the connection path CN, and the light receiving unit 40 are simultaneously formed.

In order to implement the window structure region WG, the layer R004 near the end portion where the signal light is emitted from the optical waveguide G1 is removed. As a result, state S22 is obtained.

Thereafter, a diffraction grating is formed on an upper surface of the layer R002 that functions as the semiconductor laser 10, and further, a layer R005 of a p-polar indium phosphide (InP) and a layer R006 of a p+-polar indium gallium arsenide (InGaAs) are overcladding grown to obtain state S23. According to FIG. 11, it can be seen that the layer R005 is formed in a portion corresponding to the window structure region WG.

Thereafter, each component and a side of the waveguide are buried in a layer R007 of a semi-insulating InP doped with iron (Fe).

Subsequently, the components are electrically separated from each other by removing the layer R006 between the semiconductor laser 10, the optical modulator 20, and the optical amplifier 30. Then the layer R008 to be the electrode for p-polarity is formed on the layer R006 of each component, and the layer R009 to be the back electrode is formed. As a result, state S24 is obtained.

### Description of Third Embodiment

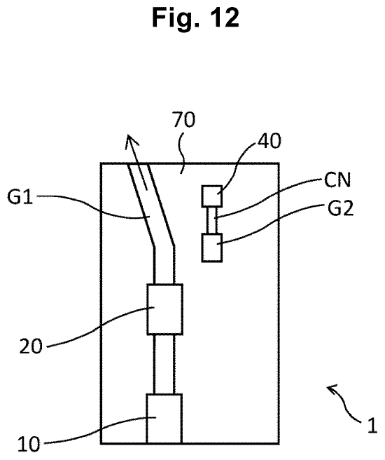

FIG. 12 is a schematic view illustrating a configuration of a semiconductor optical integrated device according to a third embodiment of the present disclosure. Unlike the first embodiment illustrated in FIG. 1, the semiconductor optical integrated device 1 illustrated in FIG. 12 does not include the optical amplifier 30. Also in the semiconductor optical integrated device 1 according to the present embodiment, part of the signal light leaking from the optical waveguide G1 reaches the gain waveguide G2. The light receiving unit 40 can indirectly measure the intensity of the signal light propagating through the optical waveguide G1 through the change in the gain of the gain waveguide G2.

### Description of Fourth Embodiment

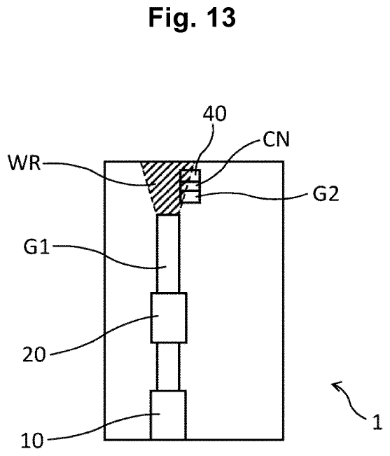

FIG. 13 is a schematic view illustrating a configuration of a semiconductor optical integrated device according to a fourth embodiment of the present disclosure. Unlike the second embodiment illustrated in FIG. 10, the semiconductor optical integrated device 1 illustrated in FIG. 13 does not include the optical amplifier 30. Also in the semiconductor optical integrated device 1 according to the present embodiment, part of the signal light propagating through the window structure region WG reaches the gain waveguide G2. The light receiving unit 40 can indirectly measure the intensity of the signal light propagating through the optical waveguide G1 through the change in the gain of the gain waveguide G2.

### Effects of Embodiment

As described above in detail, the semiconductor optical integrated device according to the present embodiment includes the semiconductor laser, the optical modulator that modulates light emitted from the semiconductor laser to generate signal light, the optical waveguide that propagates the signal light, the gain waveguide formed adjacent to the optical waveguide, and the light receiving unit connected to the gain waveguide, which are monolithically integrated. A gain of the gain waveguide is varied by part of the signal light from the optical waveguide, and the light receiving unit acquires an intensity of natural radiation amplified light propagating through the gain waveguide.

As a result, it is possible to measure a light intensity of emitted light while suppressing an increase in size of the entire module. In particular, it is not necessary to separately provide a configuration for measuring the light intensity of the light emitted from the semiconductor optical integrated device, and it is possible to suppress an increase in size of the entire module including the semiconductor optical integrated device.

In addition, the intensity of the signal light can be accurately acquired without being affected by degradation rates of characteristics that can be different for each component of the semiconductor optical integrated device. As a result, even when the semiconductor optical integrated device is operated for a long period of time, the intensity of the signal light can be adjusted so as to be maintained constant.

In addition, the semiconductor optical integrated device according to the present embodiment may include the semiconductor region between the optical waveguides, and may vary the gain by part of the signal light propagating through the semiconductor region. As a result, it is possible to accurately acquire the intensity of the signal light while suppressing an increase in size of the entire module.

Furthermore, in the semiconductor optical integrated device according to the present embodiment, the semiconductor region may be the window structure region that propagates the signal light from the optical waveguide to the end surface of the semiconductor optical integrated device. As a result, the window structure region for emitting the signal light from the semiconductor optical integrated device can be used for measuring the signal light, and the semiconductor optical integrated device can be decreased in size.

In addition, the semiconductor optical integrated device according to the present embodiment may vary the gain in the gain saturation range of the gain waveguide. As a result, the gain of the gain waveguide can be efficiently varied by part of the signal light from the optical waveguide. As a result, a correlation of the intensity of the natural radiation amplified light generated in the gain waveguide with the intensity of the signal light from the optical waveguide can be increased, and the intensity of the signal light can be accurately acquired.

Furthermore, in the semiconductor optical integrated device according to the present embodiment, the connection path between the gain waveguide and the light receiving unit may be configured to propagate the natural radiation amplified light and not to propagate the signal light. As a result, it is possible to suppress optical coupling of the signal light propagating through the optical waveguide to the gain waveguide. As a result, it is possible to suppress a decrease in the intensity of the signal light emitted from the semiconductor optical integrated device.

In the semiconductor optical integrated device according to the present embodiment, the distance between the optical waveguide and the gain waveguide may be set based on at least one of the thickness and the width of the optical waveguide. As a result, the intensity of the signal light leaking from the optical waveguide and reaching the gain waveguide can be adjusted.

Furthermore, the semiconductor optical integrated device according to the present embodiment may include the monolithically integrated optical amplifier that amplifies the signal light, and the optical waveguide may propagate the signal light amplified by the optical amplifier. As a result, even when degradation rates of the characteristics of the semiconductor laser and the optical modulator are different from degradation rates of the characteristics of the optical amplifier, the intensity of the signal light can be accurately acquired. As a result, even when the semiconductor optical integrated device including the optical amplifier is operated for a long period of time, the intensity of the signal light after amplification can be adjusted so as to be maintained constant by the optical amplifier.

Although the contents of the present disclosure have been described above according to the embodiment, the present disclosure is not limited to the description thereof, and it is obvious to those skilled in the art that various modifications and improvements can be made. It should not be construed that the present disclosure is limited to the statements and the drawings that constitute part of the present disclosure. Various alternative embodiments, examples, and operating techniques will be apparent to those skilled in the art from this disclosure.

It is needless to say that the present disclosure includes various embodiments and the like that are not described herein. Therefore, the technical scope of the present disclosure is defined only by the invention-specifying matters according to the claims appropriate from the above description.

### Reference Signs List

1 semiconductor optical integrated device
10 semiconductor laser
20 optical modulator
30 optical amplifier
40 light receiving unit
70 semiconductor region
CN connection path
G1 optical waveguide
G2 gain waveguide
WG window structure region

1. A semiconductor optical integrated device comprising:
a semiconductor laser;
an optical modulator configured to modulate light emitted from the semiconductor laser to generate signal light;
an optical waveguide configured to propagate the signal light;
a gain waveguide formed adjacent to the optical waveguide; and
a light receiving unit connected to the gain waveguide, which are monolithically integrated, wherein
a gain of the gain waveguide is varied by part of the signal light from the optical waveguide, and
the light receiving unit acquires an intensity of natural radiation amplified light propagating through the gain waveguide.

2. The semiconductor optical integrated device according to claim 1, further comprising a semiconductor region between the optical waveguides, wherein
the gain is varied by part of the signal light propagating through the semiconductor region.

3. The semiconductor optical integrated device according to claim 2, wherein the semiconductor region is a window structure region configured to propagate the signal light from the optical waveguide to an end surface of the semiconductor optical integrated device.

4. The semiconductor optical integrated device according to claim 1, wherein the gain is varied in a gain saturation range of the gain waveguide.

5. The semiconductor optical integrated device according to claim 1, wherein a connection path between the gain waveguide and the light receiving unit is configured to propagate the natural radiation amplified light and not to propagate the signal light.

6. The semiconductor optical integrated device according to claim 1, wherein a distance between the optical waveguide and the gain waveguide is set based on at least one of the thickness and the width of the optical waveguide.

7. The semiconductor optical integrated device according to claim 1, further comprising a monolithically integrated optical amplifier configured to amplify the signal light, wherein
the optical waveguide propagates the signal light amplified by the optical amplifier.
